(19) United States
(12) Patent Application Publication
(10) Pub. No.: US 2015/0340460 A1
(43) Pub. Date: Nov. 26, 2015

(54) ADVANCED TRANSISTORS WITH THRESHOLD VOLTAGE SET DOPANT STRUCTURES

(71) Applicant: MIE Fujitsu Semiconductor Limited, Kuwana (JP)

(72) Inventors: Lucian Shifren, San Jose, CA (US); Pushkar Ranade, Los Gatos, CA (US); Lance Scudder, Sunnyvale, CA (US)

(21) Appl. No.: 14/811,985

(22) Filed: Jul. 29, 2015

Related U.S. Application Data
(62) Division of application No. 12/895,785, filed on Sep. 30, 2010.
(60) Provisional application No. 61/262,122, filed on Nov. 17, 2009.
(60) Provisional application No. 61/247,300, filed on Sep. 30, 2009.
(60) Provisional application No. 61/357,492, filed on Jun. 22, 2010.

(51) Int. Cl. H01L 29/66; H01L 21/265

(52) U.S. Cl. CPC H01L 29/66537; H01L 21/265

(57) ABSTRACT

An advanced transistor with threshold voltage set dopant structure includes a gate with length Lg and a well doped to have a first concentration of a dopant. A screening region is positioned between the well and the gate and has a second concentration of dopant greater than 5×10¹⁸ dopant atoms per cm³. A threshold voltage set region is formed by placement of a threshold voltage offset plane positioned above the screening region. The threshold voltage set region may be formed by delta doping and have a thickness between Lg/5 and Lg/1 The structure uses minimal or no halo implants to maintain channel dopant concentration at less than 5×10¹⁷ dopant atoms per cm³.

### RELATED APPLICATIONS

This application claims the benefit of U.S. Provisional Application No. 61/247,300, filed Sep. 30, 2009, the disclosure of which is incorporated by reference herein. This application also claims the benefit of U.S. Provisional Application No. 61/262,122, filed Nov. 17, 2009, the disclosure of which is incorporated by reference herein, and U.S. patent application Ser. No. 12/708,497 , titled “Electronic Devices and Systems, and Methods for Making and Using the Same”, filed Feb. 18, 2010, the disclosure of which is incorporated by reference herein. This application also claims the benefit of U.S. Provisional Application No. 61/357,492, filed Jun. 22, 2010, the disclosure of which is incorporated by reference herein.

### FIELD OF THE INVENTION

This disclosure relates to structures and processes for forming advanced transistors with improved operational characteristics, including threshold voltage set dopant structures.

### BACKGROUND OF THE INVENTION

The voltage at which a field effect transistor (FET) is switched on or off is a key parameter for transistor operation. Transistors that have a low threshold voltage (V_{T}), typically about 0.3 times the operating voltage (V_{DD}), are able to quickly switch but also have a relatively high off state current leakage. Transistors that have a high threshold voltage (V_{T}), typically about 0.7 times the operating voltage (V_{DD}), switch more slowly, but have a relatively low off state current leakage. Semiconductor electronic designers have taken advantage of this by manufacturing die with multiple transistor devices having differing threshold voltages, with high speed critical pathways having a low V_{T}, and more infrequently accessed circuits having a power saving high V_{T}

Conventional solutions for setting V_{T} include doping a transistor channel with a V_{T} implant. Typically, the higher the implant dosage, the higher the device V_{T}. The channel can also be doped by high implant angle “pocket” or “halo” implants around the source and the drain. Channel V_{T} implants and halo implants can symmetrical or asymmetrical with respect to a transistor source and drain, and both taken together increase the V_{T} to a desired level. Unfortunately, such implants adversely affect electron mobility, primarily because of the increased dopant scattering in the channel, and required dopant densities and implant position control for a useful V_{T} set point in nanoscale transistors are increasingly difficult to support as transistors are scaled downward in size.

Many semiconductor manufacturers have attempted to avoid scaling issues with bulk CMOS (including adverse “short channel effects” in transistors with nanoscale gate transistor sizes) by employing new transistor types, including fully or partially depleted silicon on insulator (SOI) transistors. SOI transistors are built on a thin layer of silicon that overlies an insulator layer, and generally require V_{T} setting channel implants or halo implants for operation. Unfortunately, creating a suitable insulator layer is expensive and difficult to accomplish. Early SOI devices were built on insulative sapphire wafers instead of silicon wafers, and are typically only used in specialty applications (e.g. military avionics or satellite) because of the high costs. Modern SOI technology can use silicon wafers, but require expensive and time consuming additional wafer processing steps to make an insulative silicon oxide layer that extends across the entire wafer below a surface layer of device-quality single-crystal silicon.

One common approach to making such a silicon oxide layer on a silicon wafer requires high dose ion implantation of oxygen and high temperature annealing to form a buried oxide (BOX) layer in a bulk silicon wafer. Alternatively, SOI wafers can be fabricated by bonding a silicon wafer to another silicon wafer (a “handle” wafer) that has an oxide layer on its surface. The pair of wafers are split apart, using a process that leaves a thin transistor quality layer of single crystal silicon on top of the BOX layer on the handle wafer. This is called the “layer transfer” technique, because it transfers a thin layer of silicon onto a thermally grown oxide layer of the handle wafer.

As would be expected, both BOX formation or layer transfer are costly manufacturing techniques with a relatively high failure rate. Accordingly, manufacture of SOI transistors not an economically attractive solution for many leading manufacturers. When cost of transistor redesign to cope with “floating body” effects, the need to develop new SOI specific transistor processes, and other circuit changes is added to SOI wafer costs, it is clear that other solutions are needed.

Another possible advanced transistor that has been investigated uses multiple gate transistors that, like SOI transistors, minimize adverse scaling and short channel effects by having little or no doping in the channel. Commonly known as a finFET (due to a fin-like shaped channel partially surrounded by gates), use of finFET transistors has been proposed for transistors having 28 nanometer or lower transistor gate size. But again, like SOI transistors, while moving to a radically new transistor architecture solves some scaling, V_{T} set point, and short channel effect issues, it creates others, requiring even more significant transistor layout redesign than SOI. Considering the likely need for complex non-planar transistor manufacturing techniques to make a finFET, and the unknown difficulty in creating a new process flow for finFET, manufacturers have been reluctant to invest in semiconductor fabrication facilities capable of making finFETs.

### BRIEF DESCRIPTION OF THE DRAWINGS

FIG. 1 illustrates a DDC transistor with improved threshold voltage set region dopant structures;

FIG. 2 illustrates one a dopant profile with threshold voltage set region dopant structures;

FIG. 3 schematically illustrates pre-anneal threshold voltage dopant profile ; and

FIG. 4 illustrates a typical process flow supporting delta doped V_{T} structures.

### DETAILED DESCRIPTION

Nanoscale bulk CMOS transistors (those typically having a gate length less than 100 nanometers) are increasingly difficult to manufacture in part because V_{T} scaling does not match V_{DD} scaling. Normally, for transistors having a gate size greater than 100 nanometers, reduction in gate length of a transistor included a roughly proportional reduction in operating voltage V_{DD}, which together ensured a roughly equivalent electrical field and operating characteristics. The ability to reduce the operating voltage V_{DD}, depends in part on being able to accurately set the threshold voltage V_{T}, but that has become increasingly difficult as transistor dimensions decrease because of a variety of factors, including, for example, Random Dopant Fluctuation (RDF). For transistors made using bulk CMOS processes, the primary parameter that sets the threshold voltage V_{T} is the amount of dopants in the channel. In theory, this can be done precisely, such that the same transistors on the same chip will have the same V_{T}, but in reality the threshold voltages can vary significantly. This means that these transistors will not all switch on at the same time in response to the same gate voltage, and some may never switch on. For nanoscale transistors having a gate and channel length of 100 nm or less, RDF is a major determinant of variations in V_{T}, typically referred to as sigmaV_{T} or σV_{T}, and the amount of σV_{T} caused by RDF only increases as channel length decreases.

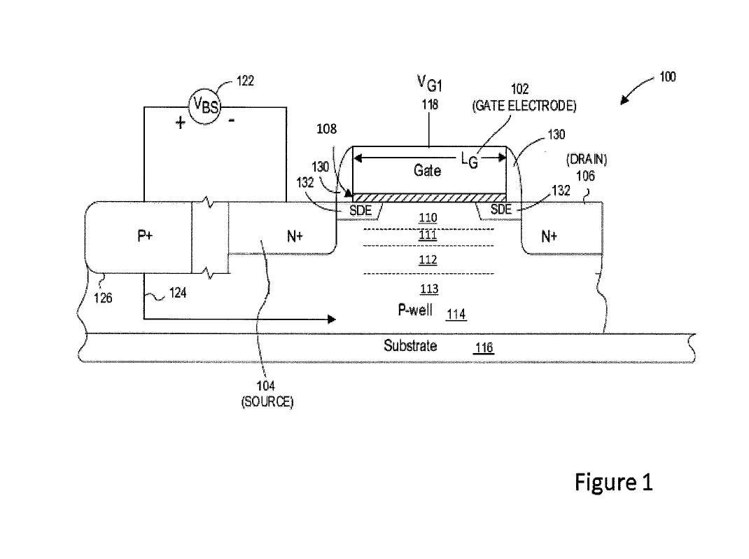

An improved transistor manufacturable on bulk CMOS substrates using conventional planar CMOS processes is seen in FIG. 1. A Field Effect Transistor (FET) 100 is configured to have greatly reduced short channel effects, along with an ability to precisely set threshold voltage Vt according to certain described embodiments. The FET 100 includes a gate electrode 102, source 104, drain 106, and a gate dielectric 108 positioned over a channel 110. In operation, the channel 110 is deeply depleted, forming what can be described as deeply depleted channel (DDC) as compared to conventional transistors, with depletion depth set in part by a highly doped screening region 112. While the channel 110 is substantially undoped, and positioned as illustrated above a highly doped screening region 112, it may include simple or complex layering with different dopant concentrations. This doped layering can include a threshold voltage set region 111 with a dopant concentration less than screening region 112, optionally positioned between the gate dielectric 108 and the screening region 112 in the channel 110. A threshold voltage set region 111 permits small adjustments in operational threshold voltage of the FET 100, while leaving the bulk of the channel 110 substantially undoped. In particular, that portion of the channel 110 adjacent to the gate dielectric 108 should remain undoped. Additionally, a punch through suppression region 113 is formed beneath the screening region 112. Like the threshold voltage set region 111, the punch through suppression region 113 has a dopant concentration less than screening region 112, while being higher than the overall dopant concentration of a lightly doped well substrate 114.

In operation, a bias voltage 122 V_{BS} may be applied to source 104 to further modify operational threshold voltage, and P+ terminal 126 can be connected to P-well 114 at connection 124 to close the circuit. The gate stack includes a gate electrode 102, gate contact 118 and a gate dielectric 108. Gate spacers 130 are included to separate the gate from the source and drain, and optional Source/Drain Extensions (SDE) 132, or “tips” extend the source and drain under the gate spacers and gate dielectric 108, somewhat reducing the gate length and improving electrical characteristics of FET 100.

In this exemplary embodiment, the FET 100 is shown as an N-channel transistor having a source and drain made of N-type dopant material, formed upon a substrate as P-type doped silicon substrate providing a P-well 114 formed on a substrate 116. However, it will be understood that, with appropriate change to substrate or dopant material, a non-silicon P-type semiconductor transistor formed from other suitable substrates such as Gallium Arsenide based materials may be substituted. The source 104 and drain 106 can be formed using conventional dopant implant processes and materials, and may include, for example, modifications such as stress inducing source/drain structures, raised and/or recessed source/drains, asymmetrically doped, counter-doped or crystal structure modified source/drains, or implant doping of source/drain extension regions according to LDD (low doped drain) techniques. Various other techniques to modify source/drain operational characteristics can also be used, including, in certain embodiments, use of heterogeneous dopant materials as compensation dopants to modify electrical characteristics.

The gate electrode 102 can be formed from conventional materials, preferably including, but not limited to, metals, metal alloys, metal nitrides and metal silicides, as well as laminates thereof and composites thereof. In certain embodiments the gate electrode 102 may also be formed from polysilicon, including, for example, highly doped polysilicon and polysilicon-germanium alloy. Metals or metal alloys may include those containing aluminum, titanium, tantalum, or nitrides thereof, including titanium containing compounds such as titanium nitride. Formation of the gate electrode 102 can include silicide methods, chemical vapor deposition methods and physical vapor deposition methods, such as, but not limited to, evaporative methods and sputtering methods. Typically, the gate electrode 102 has an overall thickness from about 1 to about 500 nanometers.

The gate dielectric 108 may include conventional dielectric materials such as oxides, nitrides and oxynitrides. Alternatively, the gate dielectric 108 may include generally higher dielectric constant dielectric materials including, but not limited to hafnium oxides, hafnium silicates, zirconium oxides, lanthanum oxides, titanium oxides, barium-strontium-titanates and lead-zirconate-titanates, metal based dielectric materials, and other materials having dielectric properties. Preferred hafnium-containing oxides include HfO₂, HfZrOₓ, HfSiOₓ, HfTiOₓ, HfAlOₓ, and the like. Depending on composition and available deposition processing equipment, the gate dielectric 108 may be formed by such methods as thermal or plasma oxidation, nitridation methods, chemical vapor deposition methods (including atomic layer deposition methods) and physical vapor deposition methods. In some embodiments, multiple or composite layers, laminates, and compositional mixtures of dielectric materials can be used. For example, a gate dielectric can be formed from a SiO₂-based insulator having a thickness between about 0.3 and 1 nm and the hafnium oxide based insulator having a thickness between 0.5 and 4 nm. Typically, the gate dielectric has an overall thickness from about 0.5 to about 5 nanometers The channel region 110 is formed below the gate dielectric 108 and above the highly doped screening region 112. The channel region 110 also contacts and extends between, the source 104 and the drain 106. Preferably, the channel region includes substantially undoped silicon having a dopant concentration less than 5×10¹⁷ dopant atoms per cm³ adjacent or near the gate dielectric 108. Channel thickness can typically range from 5 to 50 nanometers. In certain embodiments the channel region 110 is formed by epitaxial growth of pure or substantially pure silicon on the screening region.

As disclosed, the threshold voltage set region 111 is positioned above screening region 112, and is typically formed as a thin doped layer. In certain embodiments, delta doping, controlled in-situ deposition, or atomic layer deposition can be used to form dopant plane that is substantially parallel and vertically offset with respect to the screening region 112. Suitably varying dopant concentration, thickness, and separation from the gate dielectric and the screening region allows for controlled slight adjustments of threshold voltage in the operating FET 100. In certain embodiments, the threshold voltage set region 111 is doped to have a concentration between about 1×10¹⁸ dopant atoms per cm³ and about 1×10¹⁹ dopant atoms per cm³. The threshold voltage set region 111 can be formed by several different processes, including 1) in-situ epitaxial doping, 2) epitaxial growth of a thin layer of silicon followed by a tightly controlled dopant implant (e.g delta doping), 3) epitaxial growth of a thin layer of silicon followed by dopant diffusion of atoms from the screening region 112, or 4) by any combination of these processes (e.g. epitaxial growth of silicon followed by both dopant implant and diffusion from the screening layer 112).

Position of a highly doped screening region 112 typically sets depth of the depletion zone of an operating FET 100. Advantageously, the screening region 112 (and associated depletion depth) are set at a depth that ranges from one comparable to the gate length (Lg/1) to a depth that is a large fraction of the gate length (Lg/5). In preferred embodiments, the typical range is between Lg/3 to Lg/1.5. Devices having an Lg/2 or greater are preferred for extremely low power operation, while digital or analog devices operating at higher voltages can often be formed with a screening region between Lg/5 and Lg/2. For example, a transistor having a gate length of 32 nanometers could be formed to have a screening region that has a peak dopant density at a depth below the gate dielectric of about 16 nanometers (Lg/2), along with a voltage threshold set at peak dopant density at a depth of 8 nanometers (Lg/4).

In certain embodiments, the screening region 112 is doped to have a concentration between about 5×10¹⁸ dopant atoms per cm³ and about 1×10²⁰ dopant atoms per cm³, significantly more than the dopant concentration of the undoped channel, and at least slightly greater than the dopant concentration of the optional voltage threshold set region 111. As will be appreciated, exact dopant concentrations and screening region depths can be modified to improve desired operating characteristics of FET 100, or to take in to account available transistor manufacturing processes and process conditions.

To help control leakage, the punch through suppression region 113 is formed beneath the screening region 112. Typically, the punch through suppression region 113 is formed by direct implant into a lightly doped well, but it be formed by out diffusion from the screening region, in-situ growth, or other known process. Like the threshold voltage set region 111, the punch through suppression region 113 has a dopant concentration less than the screening region 122, typically set between about 1×10¹⁸ dopant atoms per cm³ and about 1×10¹⁹ dopant atoms per cm³. In addition, the punch through suppression region 113 dopant concentration is set higher than the overall dopant concentration of the well substrate. As will be appreciated, exact dopant concentrations and depths can be modified to improve desired operating characteristics of FET 100, or to take in to account available transistor manufacturing processes and process conditions.

Forming such a FET 100 is relatively simple compared to SOI or finFET transistors, since well developed and long used planar CMOS processing techniques can be readily adapted

Together, the structures and the methods of making the structures allow for FET transistors having both a low operating voltage and a low threshold voltage as compared to conventional nanoscale devices. Furthermore, DDC transistors can be configured to allow for the threshold voltage to be statically set with the aid of a voltage body bias generator. In some embodiments the threshold voltage can even be dynamically controlled, allowing the transistor leakage currents to be greatly reduced (by setting the voltage bias to upwardly adjust the V_{T} for low leakage, low speed operation), or increased (by downwardly adjusting the V_{T} for high leakage, high speed operation). Ultimately, these structures and the methods of making structures provide for designing integrated circuits having FET devices that can be dynamically adjusted while the circuit is in operation. Thus, transistors in an integrated circuit can be designed with nominally identical structure, and can be controlled, modulated or programmed to operate at different operating voltages in response to different bias voltages, or to operate in different operating modes in response to different bias voltages and operating voltages. In addition, these can be configured post-fabrication for different applications within a circuit.

As will be appreciated, concentrations of atoms implanted or otherwise present in a substrate or crystalline layers of a semiconductor to modify physical and electrical characteristics of a semiconductor are be described in terms of physical and functional regions or layers. These may be understood by those skilled in the art as three-dimensional masses of material that have particular averages of concentrations. Or, they may be understood as sub-regions or sub-layers with different or spatially varying concentrations. They may also exist as small groups of dopant atoms, regions of substantially similar dopant atoms or the like, or other physical embodiments. Descriptions of the regions based on these properties are not intended to limit the shape, exact location or orientation. They are also not intended to limit these regions or layers to any particular type or number of process steps, type or numbers of layers (e.g., composite or unitary), semiconductor deposition, etch techniques, or growth techniques utilized. These processes may include epitaxially formed regions or atomic layer deposition, dopant implant methodologies or particular vertical or lateral dopant profiles, including linear, monotonically increasing, retrograde, or other suitable spatially varying dopant concentration. To ensure that desired dopant concentrations are maintained, various dopant anti-migration techniques, are contemplated, including low temperature processing, carbon doping, in-situ dopant deposition, and advanced flash or other annealing techniques. The resultant dopant profile may have one or more regions or layers with different dopant concentrations, and the variations in concentrations and how the regions or layers are defined, regardless of process, may or may not be detectable via techniques including infrared spectroscopy, Rutherford Back Scattering (RBS), Secondary Ion Mass Spectroscopy (SIMS), or other dopant analysis tools using different qualitative or quantitative dopant concentration determination methodologies.

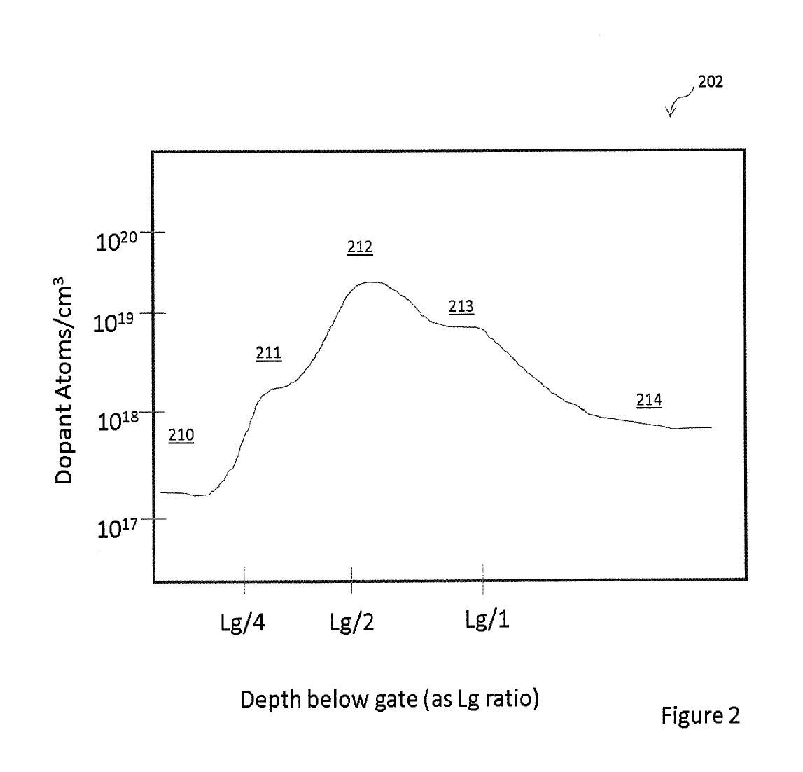

To better appreciate one possible transistor structure that includes a sharply defined threshold voltage set formed by deposition of a threshold voltage offset plane, FIG. 2 illustrates a dopant profile 202 of a deeply depleted transistor taken at midline between a source and drain, and extending downward from a gate dielectric toward a well. Concentration is measured in number of dopant atoms per cubic centimeter, and downward depth is measured as a ratio of gate length Lg. Measuring as a ratio rather than absolute depth in nanometers better allows cross comparison between transistors manufactured at different nodes (e.g 45 nm, 32 nm, 22 nm, or 15 nm) where nodes are commonly defined in term of minimum gate lengths.

As seen in FIG. 2, the region of the channel 210 adjacent to the gate dielectric is substantially free of dopants, having less than 5×10¹⁷ dopant atoms per cm³ to a depth of nearly Lg/4. A threshold voltage set region 211 increases the dopant concentration to about 3×10¹⁸ dopant atoms per cm³ , and the concentration increases another order of magnitude to about 3×10¹⁹ dopant atoms per cm³ to form the screening region 212 that sets the base of the depletion zone in an operating transistor. A punch through suppression region 213 region having a dopant concentration of about 1×10¹⁹ dopant atoms per cm³ at a depth of about Lg/1 is intermediate between the screening region and the lightly doped well 214. Without the punch through suppression region, a transistor constructed to have, for example, an 30 nm gate length and an operating voltage of 1.0 volts would be expected to have significantly greater leakage. When the disclosed punch through suppression 213 is implanted, punch through leakage is reduced, making the transistor more power efficient, and better able to tolerate process variations in transistor structure without punch through failure.

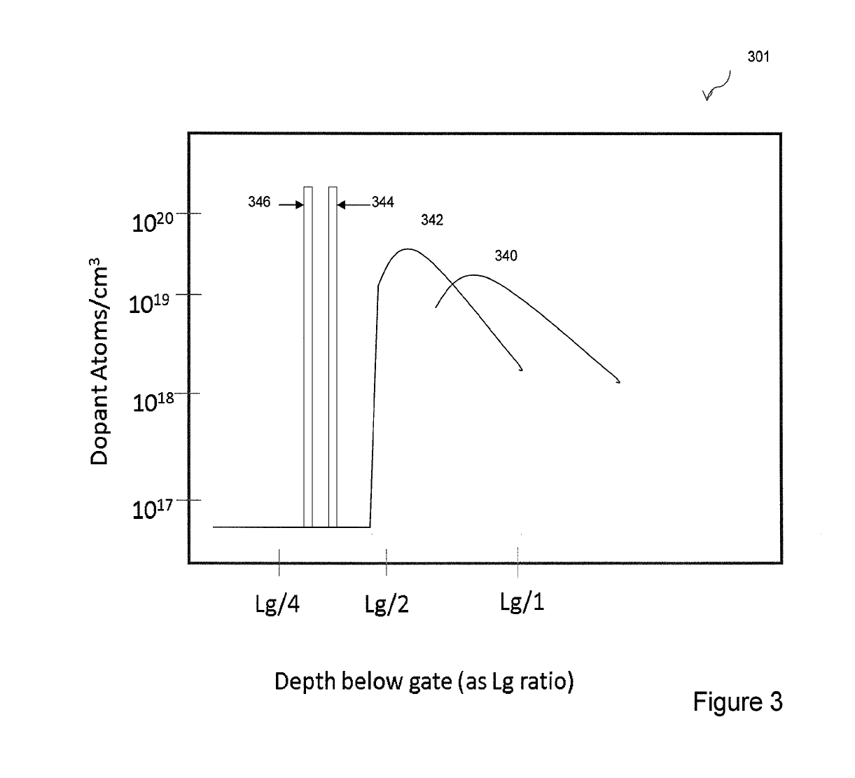

While deep dopant implants capable of forming the punch through suppression region and screening region are relatively easy to control, it is much more difficult to form with high precision a threshold voltage set region. Dopant migration from the screening region can cause substantial variations in placement and concentration of the threshold voltage set region, particularly when high temperature processes often encountered to activate dopants are used. One contemplated embodiment that reduces unwanted dopant variations is illustrated in FIG. 3. Graph 301 illustrates pre-anneal dopant implant concentrations in a dopant profile that results in a dopant profile structure such as discussed with respect to FIG. 2. As is apparent, separate dopant implants 340 and 342 are used to respectively form the punch through suppression region and the screening region. Epitaxial silicon is grown, with pure silicon deposition interrupted twice by delta doping to form threshold voltage offset planes 344 and 346. These multiple planes are extremely thin, on the order of one or two atomic layers thick, and extremely concentrated in dopants. One or more threshold voltage offset planes can be positioned anywhere in epitaxial channel, but are preferably positioned at distance of at least Lg/5 from the gate dielectric. Post-anneal, the threshold voltage offset planes slightly diffuse, forming a desired threshold voltage set region as illustrated with respect to FIG. 2.

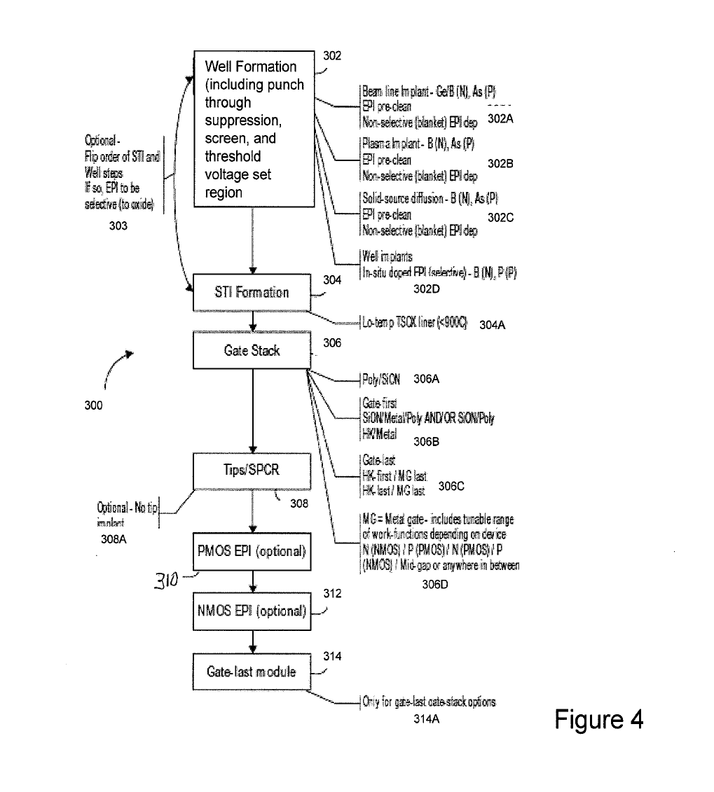

Delta doped planes can be deposited by molecular beam epitaxy, organometallic decomposition, atomic layer deposition or other conventional processing techniques, including chemical or physical vapor deposition. One embodiment of a suitable process for forming a delta doped offset plane positioned below a substantially undoped channel and above a screen region is schematically illustrated in FIG. 4.

FIG. 4 is a process flow diagram 300 illustrating one exemplary process for forming a transistor with a delta doped offset plane, a punch through suppression region and a screening region suitable for different types of FET structures, including both analog and digital transistors. The process illustrated here is intended to be general and broad in its description in order not to obscure the inventive concepts, and more detailed embodiments and examples are set forth below. These along with other process steps allow for the processing and manufacture of integrated circuits that include DDC structured devices together with legacy devices, allowing for designs to cover a full range of analog and digital devices with improved performance and lower power.

In Step 302, the process begins at the well formation, which may be one of many different processes according to different embodiments and examples. As indicated in 303, the well formation may be before or after STI (shallow trench isolation) formation 304, depending on the application and results desired. Boron (B), indium (I) or other P-type materials may be used for P-type implants, and arsenic (As) or phosphorous (P) and other N-type materials may be used for N-type implants. For the PMOS well implants, the P+ implant may be implanted within a range from 10 to 80 keV, and at concentrations from 1×10¹³ to 8×10¹³ /cm². As+ may be implanted within a range of 5 to 60 keV, and at concentrations from 1×10¹³ to 8×10¹³/cm². For NMOS well implants, the boron implant B+ implant may be within a range of 0.5 to 5 keV, and within a concentration range of 1×10¹³ to 8×10¹³/cm². A germanium implant Ge+, may be performed within a range of 10 to 60 keV, and at a concentration of 1×10¹⁴ to 5×10¹⁴ /cm². To reduce dopant migration, a carbon implant, C+ may be performed at a range of 0.5 to 5 keV, and at a concentration of 1×10¹³ to 8×10¹³/cm². Well implants may include sequential implant, and/or epitaxial growth and implant, of punch through suppression regions, screen regions having a higher dopant density than the punch through suppression region, and threshold voltage set regions (which previously discussed are typically formed by implant or diffusion of dopants into a grown epitaxial layer on the screening region).

In some embodiments the well formation 302 may include a beam line implant of Ge/B (N), As (P), followed by an epitaxial (EPI) pre-clean process, and followed finally non-selective blanket EPI deposition, as shown in 302A. Alternatively, the well may be formed using a plasma implant of B (N), As (P), followed by an EPI pre-clean, then finally a non-selective (blanket) EPI deposition, 302B. Delta doping can occur at suitable stages during EPI growth, and multiple EPI growth/delta dope stages are contemplated if needed to form a desired post anneal dopant profile with a desired V_{T} set point. The well formation may alternatively include a solid-source diffusion of B(N), As(P), followed by an EPI pre-clean, and followed finally by a non-selective (blanket) EPI deposition, 302C. The well formation may alternatively include a solid-source diffusion of B(N), As(P), followed by an EPI pre-clean, and followed finally by a non-selective (blanket) EPI deposition, 302D. As yet another alternative, well formation may simply include well implants, followed by in-situ doped selective EPI of B (N), P (P). Embodiments described herein allow for any one of a number of devices configured on a common substrate with different well structures and according to different parameters.

Shallow trench isolation (STI) formation 304, which, again, may occur before or after well formation 302, may include a low temperature trench sacrificial oxide (TSOX) liner at a temperature lower than 900° C. The gate stack 306 may be formed or otherwise constructed in a number of different ways, from different materials, and of different work functions. One option is a poly/SiON gate stack 306A. Another option is a gate-first process 306B that includes SiON/Metal/Poly and/or SiON/Poly, followed by High-K/Metal Gate. Another option, a gate-last process 306C includes a high-K/metal gate stack wherein the the gate stack can either be formed with “Hi-K first-Metal gate last” flow or and “Hi-K last-Metal gate last” flow. Yet another option, 306D is a metal gate that includes a tunable range of work functions depending on the device construction, N(NMOS)/P(PMOS)/N(PMOS)/P(NMOS)/Mid-gap or anywhere in between. In one example, N has a work function (WF) of 4.05V±200 mV, and P has a WF of 5.01V+200 mV.

Next, in Step 308, Source/Drain tips may be implanted, or optionally may not be implanted depending on the application. The dimensions of the tips can be varied as required, and will depend in part on whether gate spacers (SPCR) are used. In one option, there may be no tip implant in 308A. Next, in optional steps 310 and 312, PMOS or NMOS EPI layers may be formed in the source and drain regions as performance enhancers for creating strained channels. For gate-last gate stack options, in Step 314, a Gate-last module is formed. This may be only for gate-last processes 314A.

Die supporting multiple transistor types, including those with and without a punch through suppression, those having different threshold voltages, those with and without threshold voltage being set in part by delta doped threshold voltage structures, and with and without static or dynamic biasing are contemplated. Systems on a chip (SoC), advanced microprocessors, radio frequency, memory, and other die with one or more digital and analog transistor configurations can be incorporated into a device using the methods described herein. According to the methods and processes discussed herein, a system having a variety of combinations of DDC and/or transistor devices and structures with or without punch through suppression can be produced on silicon using bulk CMOS. In different embodiments, the die may be divided into one or more areas where dynamic bias structures, static bias structures or no-bias structures exist separately or in some combination. In a dynamic bias section, for example, dynamically adjustable devices may exist along with high and low V_{T} devices and possibly DDC logic devices.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art. Accordingly, the specification and drawings are to be regarded in an illustrative rather than a restrictive sense.

1-5. (canceled)

6. A method for forming a field effect transistor structure, comprising the steps of
forming a well doped to have a first concentration of a dopant,
implanting a screening region into the well having a dopant concentration dopant of greater than 5×10¹⁸ dopant atoms per cm³,
growing an epitaxial layer on top of the screening region, the epitaxial layer having a thickness selected to be between about Lg/5 and about Lg/1,
forming a threshold voltage offset plane in the layer grown on the screening region, and
forming a gate having gate length Lg between a source and a drain, and above the screening region.

7. The method of claim 6 for forming a field effect transistor structure, wherein the step of forming a threshold voltage offset plane in the layer grown on the screening region further comprises the step of delta doping.

8. The method of claim 6 for forming a field effect transistor structure, wherein the step of forming a threshold voltage set offset plane in the layer grown on the screening region further comprises multiple delta doping.

9. A method for adjusting threshold voltage of a field effect transistor structure with minimal or no halo implants, comprising the steps of
implanting a screening region having a dopant concentration dopant of greater than 5×10¹⁸ dopant atoms per cm³,
growing a layer on top of the screening region having a thickness selected to be between about Lg/5 and about Lg/1,
forming a threshold voltage set region t in the layer grown on the screening region,
minimizing halo or other dopant implant dosage levels to maintain channel dopant concentration at less than 5×10¹⁷ dopant atoms per cm³, and
forming a gate having gate length Lg between a source and a drain, and above the screening region.

10. The method of claim 9 for forming a field effect transistor structure, wherein the step of forming a threshold voltage set region further comprises deposition of a threshold voltage offset plane in the layer grown on the screening region.

11. The method of claim 10 for forming a field effect transistor structure, wherein the step of forming a threshold voltage set offset plane in the layer grown on the screening region further comprises delta doping.
